(19) United States
(12) Patent Application Publication
(10) Pub. No.: US 2026/0182042 A1
(43) Pub. Date: Jun. 25, 2026

(54) Electronic device with irregular die perimeter for increased beachfront input/output capacity

(71) Applicant: Marvell Asia Pte Ltd, Singapore (SG)

(72) Inventors: Kazin Simon Blacklow, Burlington, VT (US); Zachary Baldwin, Burlington, VT (US); Wolfgang Sauter, Starksboro, VT (US)

(21) Appl. No.: 19/424,182

(22) Filed: Dec. 18, 2025

Related U.S. Application Data
(60) Provisional application No. 63/736,326, filed on Dec. 19, 2024.

(51) Int. Cl. H10D 89/10; H10B 80/00; H10D 80/30; H10D 86/01; H10W 90/10

(52) U.S. Cl. CPC H10D 89/10; H10D 80/30; H10D 86/01; H10W 90/10; H10B 80/00

(57) ABSTRACT

An electronic device includes a substrate and a semiconductor die formed over the substrate, the semiconductor die includes: (i) a core region containing at least logic circuitry, and (ii) a beachfront region surrounding at least part of the core region, the beachfront region includes a plurality of interface circuits configured to exchange signals between the core region and at least an external device, and the semiconductor die has an irregular perimeter.

### CROSS-REFERENCE TO RELATED APPLICATIONS

This application claims the benefit of U.S. Provisional Patent Application 63/736,326, filed Dec. 19, 2024, whose disclosure is incorporated herein by reference.

### FIELD OF THE DISCLOSURE

The present invention generally relates to dies in electronic devices, and more specifically to improved techniques for increasing input/output interface capacity through irregular die shapes having irregular perimeters.

### BACKGROUND

Electronic devices comprising one or more semiconductor dies face increasing challenges in input/output interface capacity, as the logic and memory components of the core of these dies scale at a faster rate than interface technologies. In such devices, the term “beachfront” or “beachfront region” of a semiconductor die refers to the perimeter region where interfaces are typically located. Beachfront region becomes a critical limiting factor for both performance and cost optimization. Traditional rectangular die shapes provide a limited beachfront region relative to the total die size, restricting the placement of high-speed interfaces such as Serializer/Deserializer (SerDes) interfaces, die-to-die connections, and memory interfaces. As bandwidth requirements continue to grow and analog circuits for high-speed operation fail to scale proportionally with transistor miniaturization, some die sizes become constrained more by their interface requirements than by their core functionality. This results in higher manufacturing costs and reduced performance efficiency.

The description above is presented as a general overview of related art in this field and should not be construed as an admission that any of the information it contains constitutes prior art against the present patent application.

### SUMMARY

An embodiment of the present invention that is described herein provides an electronic device including a substrate and a semiconductor die formed over the substrate, the semiconductor die including: (i) a core region containing at least logic circuitry, and (ii) a beachfront region surrounding at least part of the core region, the beachfront region including a plurality of interface circuits configured to exchange signals between the core region and at least an external device, and the semiconductor die has an irregular perimeter.

In some embodiments, the irregular perimeter is longer than a regular square perimeter enclosing a same area. In other embodiments, at least part of the irregular perimeter has a rectilinear shape. In yet other embodiments, at least part of the irregular perimeter has a non-rectangular shape.

In some embodiments, the non-rectangular shape includes one or more protrusions extending outward from the core region. In other embodiments, the irregular perimeter surrounds at least a portion of the one or more protrusions. In yet other embodiments, the external device includes an additional semiconductor die having a given beachfront region with a complementary irregular perimeter configured to interlock with the irregular perimeter.

In some embodiments, the irregular perimeter and the complementary irregular perimeter have interlocking wavy shapes. In other embodiments, at least part of the irregular perimeter has a periodic shape. In yet other embodiments, at least part of the irregular perimeter has an aperiodic shape.

There is additionally provided, in accordance with an embodiment of the present invention, a method for fabricating an electronic device, the method including providing a substrate. A semiconductor die having an irregular perimeter formed over the substrate. The formation of the semiconductor die includes: (i) forming a core region containing at least logic circuitry, and (ii) forming a beachfront region surrounding at least part of the core region, the beachfront region including a plurality of interface circuits configured to exchange signals between the core region and at least an external device.

The present disclosure will be more fully understood from the following detailed description of the embodiments thereof, taken together with the drawings in which:

### BRIEF DESCRIPTION OF THE DRAWINGS

FIG. 1 is a schematic top view of an electronic device having a semiconductor die with an irregular perimeter, in accordance with an embodiment that is described herein;

FIG. 2 is a schematic top view of an electronic device comprising a plurality of semiconductor dies, each featuring an irregular perimeter, in accordance with another embodiment that is described herein;

FIG. 3 is a schematic top view of an electronic device having a semiconductor die with an irregular and asymmetric perimeter, in accordance with an embodiment that is described herein; and

FIG. 4 is a flowchart that schematically illustrates a method for fabricating the electronic device shown in FIG. 2, in accordance with an embodiment that is described herein.

### DETAILED DESCRIPTION OF EMBODIMENTS

Embodiments of the present disclosure that are described herein provide techniques for increasing the input/output interface capacity of semiconductor dies in electronic devices by utilizing an irregular die perimeter shape that maximizes the use of the perimeter area. In the context of the present disclosure and in the claims, the term “regular perimeter” refers to a rectilinear shape consisting of four boundary edges meeting at four ninety-degree angles. Conversely, the term “irregular perimeter” refers to all other types of perimeters, which may comprise rectilinear shapes, curved shapes, or any combination thereof. This perimeter region, also referred to herein as the “beachfront” region, represents the available space along the die edge for positioning interface circuits. As described above in the background section, traditional rectangular die shapes provide limited beachfront region for interface placement, thereby constraining device performance and increasing manufacturing costs.

In some embodiments, an electronic device comprises a substrate and one or more semiconductor dies formed over the substrate. At least one, and typically all, of the semiconductor dies feature an irregular perimeter, which increases the available beachfront region compared to a die with a regular perimeter and the same footprint. The semiconductor die comprises a core region containing at least logic circuitry and a beachfront region that surrounds at least part of the core region. The beachfront region comprises a plurality of interface circuits configured to exchange signals between the core region and external devices.

In some embodiments, the irregular perimeter may comprise various configurations, such as rectilinear shapes with rectangular protrusions extending outward from the core region, curved perimeters featuring wavy shapes or jagged shapes, or a combination of rectilinear and curved sections as described above. The wavy shapes may have (i) a periodic shape (e.g., oscillatory or sinusoidal), (ii) an aperiodic shape (i.e., having a non-repeating pattern), or (iii) a combination of periodic and aperiodic patterns, either in separate sections or integrated within the same sections. These configurations can be optimized to meet specific interface circuit requirements while preserving the structural integrity of the semiconductor die. In some embodiments, multiple semiconductor dies featuring complementary irregular perimeters may be positioned adjacent to one another on the substrate. In some embodiments, the adjacent semiconductor dies may be positioned on either a traditional package substrate or on a 2.5D interposer, so that the described techniques are applicable to both standard and advanced packaging implementations. Their irregular perimeters can be designed with interlocking patterns to increase the interface area between the dies.

In some embodiments, the disclosed techniques may be implemented using any suitable technology, including, but not limited to, plasma dicing technology. Plasma dicing utilizes chemical processes either instead of, or in addition to, traditional mechanical saws to separate individual dies from a wafer. This approach enables the creation of non-rectangular and even non-rectilinear die shapes, eliminating the constraints of straight cutting paths required by conventional dicing methods that could only support generation of regular perimeters for beachfront regions. As such, this approach provides the flexibility needed to achieve complex geometries that maximize utilization of the beachfront region. In some embodiments, the design of these non-rectangular and non-rectilinear die shapes allows for efficient tiling of dies within a semiconductor wafer, increasing the number of dies per wafer and thereby reducing the fabrication cost per die.

The disclosed techniques offer several advantages over conventional rectangular die designs. By maximizing the ratio of perimeter length to die area, the irregular perimeter allows for the placement of additional interface circuits compared to straight-edged configurations. This addresses increasing bandwidth demands without expanding the overall die footprint. This approach is particularly beneficial for applications requiring high bandwidth in die-to-die communications, such as artificial intelligence (AI) accelerators and multi-chip modules. The increased beachfront region enables more efficient data sharing between dies while maintaining or reducing overall manufacturing costs.

The description above is presented as a general overview of embodiments of the present disclosure, which are described in detail herein.

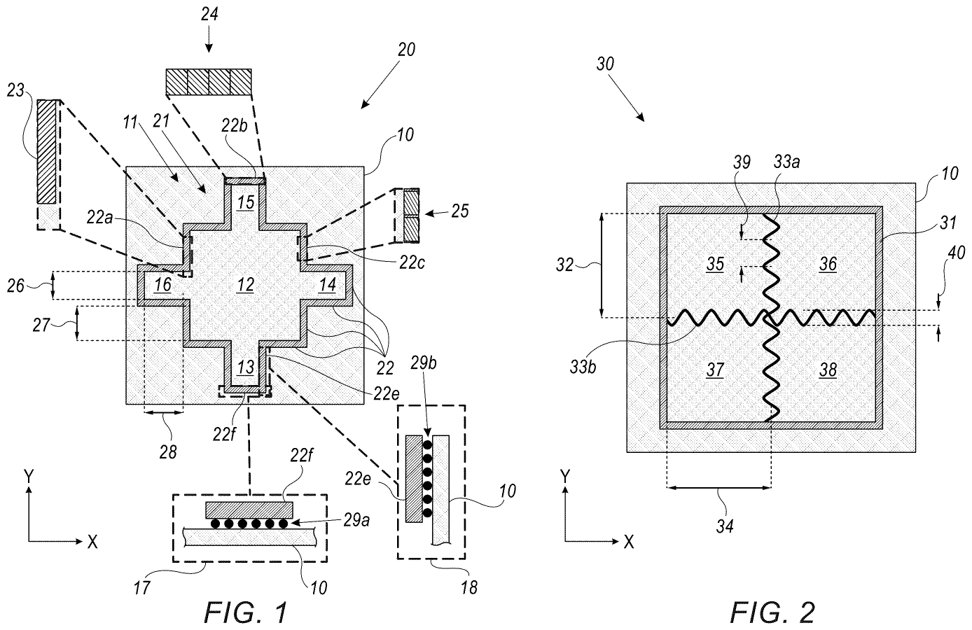

FIG. 1 is a schematic top view of an electronic device 20, in accordance with an embodiment that is described herein;

In some embodiments, electronic device 20 comprises a substrate 10, which in this example comprises an organic substrate consisting of an organic resin and fiberglass core with a number of metal and dielectric layers fabricated on both sides according to standard semiconductor packaging practice. In other embodiments, substrate 10 may comprise any other suitable type of substrate, such as a 2.5D interposer, used in advanced packaging configurations. Electronic device 20 further comprises a semiconductor die 11 (hereinafter referred to as “die 11” for brevity). Die 11 comprises a core region 21, which typically contains logic integrated circuits and memory blocks, and features a central section 12 with sections 13, 14, 15, and 16 extending from central section 12. In this example, core region 21 has a symmetric shape, so that sections 13-16 share the same geometry, with dimensions 26, 27, and 28 each being approximately 1 mm. In other embodiments, core region 21 may have an asymmetric shape with a variable size of sections 13-16. For example, at least two of sections 13-16 may differ in size and/or shape from one another, and/or at least one of dimensions 26, 27, and 28 differs from about 1 mm.

In some embodiments, die 11 comprises a beachfront region 22 that surrounds at least part of core region 21. In the present example, beachfront region 22 completely surrounds the entire perimeter of core region 21. Beachfront region 22 comprises interface circuits configured to exchange signals between core region 21 and external devices (not shown). Specifically, interface circuits 23, located in a segment 22a of beachfront region 22, are configured to exchange signals with external memory devices, such as high-bandwidth memory (HBM). Additionally, interface circuits 24 and 25, implemented in segments 22b and 22c, respectively, comprise SerDes and die-to-die connections configured to exchange signals with external logic devices.

Reference is now made to insets 17 and 18 of FIG. 1. In some embodiments, electronic device 20 comprises terminals 29a and 29b (also referred to herein as connections), shown in insets 17 and 18, respectively. Terminals 29a and 29b are positioned between (i) segments 22f and 22e of beachfront 22 of die 11 and (ii) substrate 10. Terminals 29a and 29b may comprise bumps or balls of a Ball Grid Array (BGA) configured to facilitate signal exchange between the interface circuits of beachfront region 22 and the electrical circuits implemented in substrate 10. Reference is now made back to the general view of FIG. 1. In some embodiments, only the connections located on beachfront region 22 (e.g., within a few rows of the last row of the BGA) are used for communicating signals out of die 11 or electronic device 20 (as shown in FIG. 1), or for communication between dies mounted on the same substrate 10, or on a suitable interposer, as depicted in FIG. 2 below.

In some embodiments, the non-rectangular shape of core region 21 results in an irregular shape of beachfront region 22 at the perimeter of core region 21. Additionally, in some embodiments, the irregular perimeter of die 11 is longer than that of a (hypothetical) square or rectangular die with the same area, while still complying with design rules such as those related to aspect ratio. These design rules specify that the ratio of the maximum width to height, or height to width, of a rectangular die may not exceed a certain value (e.g., less than or equal to 3). Thus, the non-rectangular shape of core region 21 and the resulting irregular shape of beachfront region 22 increase the input/output (I/O) capacity of beachfront region 22 compared to a rectangular die of the same area, without violating aspect ratio design rules. In the present implementation, device 20 can accommodate more terminals 29a and 29b than would be possible in a rectangular die of the same area with an aspect ratio less than or equal to 3.

This particular configuration of die 11 is provided as an example to illustrate certain issues, such as I/O capacity, that are addressed by embodiments of the present invention and to demonstrate how these embodiments enhance the performance of electronic device 20. However, embodiments of the present invention are not limited to these specific shapes or types of die and device, and the principles described herein may also be applied to other types of (semiconductor) dies and electronic devices.

FIG. 2 is a schematic top view of an electronic device 30, in accordance with another embodiment that is described herein. In some embodiments, electronic device 30 comprises a plurality of semiconductor dies (e.g., four dies: 35, 36, 37, and 38) arranged in a multi-chip module (MCM) configuration on a substrate 31, which may comprise, for example, an interposer mounted on package substrate 10.

In some embodiments, each of dies 35-38 features an irregular perimeter that increases the perimeter of beachfront regions 33a and 33b compared to a rectangular die with the same footprint. In some embodiments, dies 35-38 have similar dimensions, with lengths 32 and 34 along the X- and Y-axes, respectively (e.g., approximately 10 mm), and are positioned adjacent to each other in pairs. For example, dies 35 and 36 share a common beachfront region 33a, while dies 35 and 37 share another beachfront region 33b. In this example, beachfront regions 33a and 33b are identical in size and shape. The irregular perimeters of the adjacent dies are designed with complementary shapes that enable interlocking patterns, maximizing the interface area between neighboring dies. Specifically, dies 35 and 36 have complementary wavy perimeters that interlock along their shared boundary, as do dies 37 and 38. This interlocking configuration increases the die-to-die interface bandwidth by providing, compared to dies with a straight-line boundary, additional area of beachfront region 33a and 33b along the boundaries between the respective adjacent dies.

In some embodiments, the interface circuits of beachfront regions 33a and 33b comprise at least one of the following: high-speed SerDes interfaces, die-to-die interfaces, and various types of memory interfaces, including but not limited to HBM and Low Power Double Data Rate (LP-DDR) interfaces. These interface circuits are positioned along the irregular perimeters of beachfront regions 33a and 33b to take advantage of the increased area provided by the wavy-shaped perimeters.

In some embodiments, the wavy perimeters feature sinusoidal variations that form an oscillatory pattern along the die edges. An amplitude 40 and a wavelength 39 of these sinusoidal variations may be optimized to maximize the area of beachfront regions 33a and 33b, while maintaining the structural integrity of each die pair among dies 35-38 and ensuring proper alignment during the assembly of dies 35-38 in the MCM. The complementary nature of the wavy shapes allows dies 35-38 to be positioned in close proximity, thereby maximizing the perimeter length available for interface circuits.

In other embodiments, at least two of the dies 35-38 may have different sizes, shapes, or footprints. In yet other embodiments, at least one of the wavy perimeters may have an aperiodic shape (i.e., a non-repeating pattern). For example, the amplitude 40 and/or wavelength 39 may vary along the boundary between a pair of dies, such as along beachfront region 33b between dies 35 and 37.

In alternative embodiments, the boundary between an adjacent pair of dies may have a random shape that comprises any suitable rectilinear form. In these embodiments, the rectilinear shape may feature rectangular or triangular protrusions extending outward from the core region of at least one of the dies among dies 35-38, with corresponding recesses in the adjacent die to create an interlocking pattern. The irregular perimeter may also comprise non-rectangular (e.g., curved) shapes that further increase the available area of the respective beachfront region, such as one or both of beachfront regions 33a and 33b.

In some embodiments, the MCM configuration illustrated in FIG. 2 enables high-bandwidth communication between each pair of dies, among dies 35-38, by utilizing the increased interface area created by interlocking irregular perimeters. This arrangement is especially advantageous for applications such as AI accelerators and high-performance computing systems, where extensive data sharing between dies is essential. The irregular perimeters facilitate more efficient use of the available area on substrate 31 while enhancing connectivity among the plurality of dies 35-38 within the MCM.

This particular MCM configuration is shown by way of example to demonstrate how multiple dies with complementary irregular perimeters can be arranged to maximize interface capacity in multi-die electronic devices. The principles described herein may be applied to various numbers of dies and different perimeter configurations to optimize beachfront utilization for specific application requirements.

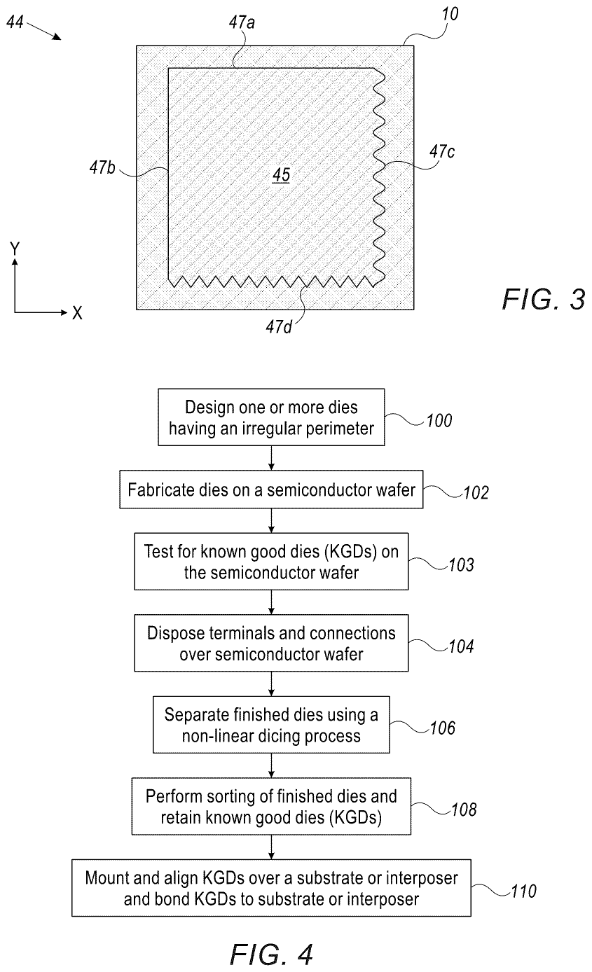

FIG. 3 is a schematic top view of an electronic device 44 having a semiconductor die 45 with an irregular and asymmetric perimeter, in accordance with an embodiment that is described herein.

In some embodiments, semiconductor die 45 comprises: (i) beachfront regions 47a and 47b, which have a regular linear shape; (ii) an irregular, wavy-shaped beachfront region 47c; and (iii) an irregular, jagged-shaped beachfront region 47d. In such embodiments, semiconductor die 45 features an asymmetric perimeter, with one side that is wavy and/or jagged and another side that is rectilinear with a regular linear shape. This configuration exemplifies an irregular perimeter that combines both rectilinear and curved or jagged sections.

FIG. 4 is a flow chart that schematically illustrates a method for fabricating electronic device 30 of FIG. 2 above, in accordance with an embodiment that is described herein. The method shown in FIG. 4 also illustrates at least part of the process for fabricating electronic device 20 depicted in FIG. 1 above.

The method begins at a die design step 100, which involves designing one or more semiconductor dies (e.g., dies 35-38 of FIG. 2 or die 11 of FIG. 1) that comprise (i) a core region containing logic circuitry and (ii) a beachfront region with interface circuits implemented around the core region, as described, for example, in FIG. 1 above. Notably, at least one (and typically all) of these semiconductor dies is designed to have an irregular perimeter. For instance, an irregular pattern of the beachfront regions (e.g., beachfront regions 33a and 33b) is defined for at least one (and typically all) of the designed dies.

At a die fabrication step 102, multiple designed dies from step 100 are fabricated on a semiconductor substrate, typically a semiconductor wafer made of silicon, germanium, gallium arsenide, or another suitable material. During step 102, the dies (e.g., dies 35-38 in FIG. 2 or die 11 in FIG. 1) are fabricated on the semiconductor wafer using any appropriate Very Large-Scale Integration (VLSI) processes known in the art.

At testing step 103, the fabricated dies (e.g., dies 35-38 in FIG. 2 or die 11 in FIG. 1) are tested to identify the known good dies (KGDs) among all fabricated dies. This process is typically performed using an electronic test system and a probe card configured for electrical testing to determine which of the tested dies are KGDs. Additionally, or alternatively, the testing process may comprise optical inspection performed to verify the quality and dimensional accuracy of the die perimeter.

At a connection formation step 104, terminals and connections (such as terminals 29a and 29b shown in FIG. 1 above) are arranged on the surface of the semiconductor wafer, at least at the location of the beachfront. In the example of FIG. 1, terminals 29a and 29b are placed in contact with beachfront 22, for example, using a wafer-level packaging (WLP) process, a Flip-Chip Ball Grid Array (FC-BGA) process, or a Chip on Wafer on Substrate (CoWoS) process. Alternatively, if the specific process requires it, step 104 may be performed at a later stage of the fabrication process, as described below.

At a dicing step 106, after concluding the fabrication of the dies on the wafer, a non-linear (e.g., irregular) dicing process is applied to separate individual finished dies (e.g., dies 35-38) from the wafer. In some embodiments, plasma dicing technology is used, which employs chemical etching instead of, or in addition to, mechanical sawing to create the irregular perimeters of beachfront regions 33a and 33b. This technology enables the formation of a wavy pattern of the perimeter of the die. The shape of the perimeter pattern may be periodic (e.g., sinusoidal) or aperiodic and may be curved, jagged, rectilinear, or having another (e.g., complex) shape of perimeter without the constraints of straight cutting paths required by conventional sawing-based dicing methods. In other embodiments, any other suitable technique may be used for separation of the individual dies from the wafer, instead of or in conjunction with the plasma dicing described above.

At a sorting step 108, the individual dies are sorted to ensure that only known good dies (KGDs), such as dies 35-38, are used in the MCM of electronic device 30. In some embodiments, sorting may be based on electrical testing and/or optical inspection performed before the dicing process in step 106, with the option of conducting an additional inspection for each individual die after step 106. Optical inspection may be used to verify the quality and dimensional accuracy of the die perimeter, ensuring that each of the individual dies 35-38 meets the design specifications.

In some embodiments, if the wafer-level packaging (WLP) is not performed in step 104, the terminals and connections (such as terminals 29a and 29b shown in FIG. 1 above) are disposed after step 108 on substrate 31 and more specifically on the beachfront regions 33a and 33b of each of the known good dies 35-38 to enable electrical connections.

At a die placement and bonding step 110, which concludes the method, known good dies (KGDs), such as dies 35-38, are mounted, aligned (e.g., in beachfront regions 33a and 33b as shown in FIG. 2 above), and bonded to substrate 31 (e.g., an interposer substrate). Additionally, substrate 31 is mounted on and bonded to (package) substrate 10, with an array of electrical connections (e.g. copper pillars or controlled collapse chip connection bumps) disposed between substrates 31 and 10, thereby completing the assembly of electronic device 30. In some embodiments, dies 35-38 are positioned on substrate 31 according to design specifications, ensuring that dies with complementary irregular perimeters are aligned to create interlocking patterns that maximize the interface area between neighboring dies.

In some embodiments, die-to-die connections are formed to facilitate communication between adjacent dies among dies 35-38, particularly those with complementary interlocking irregular perimeters. Additionally, or alternatively, die-to-substrate connections are also established through the interface circuits of the beachfront (e.g., with terminals 29a and 29b disposed over beachfront segments 22f and 22e, respectively) to enable external communication.

In some embodiments, for both FC-BGA and CoWoS processes described in step 104 above, die-to-substrate connections are established during step 110, where the die (e.g., dies 35-38) is bonded to the substrate or interposer using fine-pitch solder bumps and supporting materials. Once these internal connections are completed, the package is finished by attaching solder balls to its underside. Subsequently, during board-level assembly, the fully packaged module (e.g., electronic device 30) is mounted and soldered onto a printed circuit board (PCB), thereby creating the external interface between the package and the PCB of the system.

This method is provided as an example to illustrate the fabrication process for electronic devices with irregular die perimeters. As previously described, the sequence of steps may be modified depending on the process flow and techniques employed during fabrication. The method can be adapted for various die configurations and perimeter shapes to optimize beachfront utilization for specific application requirements.

It is noted that the embodiments described above are cited by way of example, and that the present invention is not limited to what has been particularly shown and described hereinabove. Rather, the scope of the present invention comprises both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
a substrate; and
a semiconductor die formed over the substrate, the semiconductor die comprising:
a core region containing at least logic circuitry; and
a beachfront region surrounding at least part of the core region, the beachfront region comprising a plurality of interface circuits configured to exchange signals between the core region and at least an external device,
wherein the semiconductor die has an irregular perimeter.

2. The electronic device according to claim 1, wherein the irregular perimeter is longer than a regular square perimeter enclosing a same area.

3. The electronic device according to claim 1, wherein at least part of the irregular perimeter has a rectilinear shape.

4. The electronic device according to claim 1, wherein at least part of the irregular perimeter has a non-rectangular shape.

5. The electronic device according to claim 4, wherein the non-rectangular shape comprises one or more protrusions extending outward from the core region.

6. The electronic device according to claim 5, wherein the irregular perimeter surrounds at least a portion of the one or more protrusions.

7. The electronic device of claim 1, wherein the external device comprises an additional semiconductor die having a given beachfront region with a complementary irregular perimeter configured to interlock with the irregular perimeter.

8. The electronic device of claim 7, wherein the irregular perimeter and the complementary irregular perimeter have interlocking wavy shapes.

9. The electronic device of claim 1, wherein at least part of the irregular perimeter has a periodic shape.

10. The electronic device of claim 1, wherein at least part of the irregular perimeter has an aperiodic shape.

11. A method for fabricating an electronic device, the method comprising:
providing a substrate; and
forming, over the substrate, a semiconductor die having an irregular perimeter, wherein forming the semiconductor die comprises:
forming a core region containing at least logic circuitry; and
forming a beachfront region surrounding at least part of the core region, the beachfront region comprising a plurality of interface circuits configured to exchange signals between the core region and at least an external device.

12. The method according to claim 11, wherein forming the beachfront region comprises forming the irregular perimeter to be longer than a regular square perimeter enclosing a same area.

13. The method according to claim 11, wherein forming the beachfront region comprises forming at least part of the irregular perimeter to have a rectilinear shape.

14. The method according to claim 11, wherein forming the semiconductor die comprises forming at least part of the irregular perimeter to have a non-rectangular shape.

15. The method according to claim 14, wherein forming the non-rectangular shape comprises forming one or more protrusions extending outward from the core region.

16. The method according to claim 15, wherein forming the beachfront region comprises forming the irregular perimeter to surround at least a portion of the one or more protrusions.

17. The method according to claim 11, wherein forming the external device comprises forming an additional semiconductor die having a given beachfront region with a complementary irregular perimeter for interlocking with the irregular perimeter.

18. The method according to claim 17, wherein the irregular perimeter and the complementary irregular perimeter are formed to have interlocking wavy shapes.

19. The method according to claim 11, wherein forming the beachfront region comprises forming at least part of the irregular perimeter to have a periodic shape.

20. The method according to claim 11, wherein forming the beachfront region comprises forming at least part of the irregular perimeter to have an aperiodic shape.
